(19) United States
(12) Patent Application Publication
(10) Pub. No.: US 2019/0210635 A1
(43) Pub. Date: Jul. 11, 2019

(54) VEHICLE RACK-AND-PINION MECHANISM

(71) Applicant: HONDA MOTOR CO., LTD., Tokyo (JP)

(72) Inventor: Masato SATO, Wako-shi, Saitama (JP)

(21) Appl. No.: 16/312,531

(22) PCT Filed: Jun. 30, 2017
(86) PCT No.: PCT/JP2017/024273

§ 371 Date: Dec. 21, 2018

(30) Foreign Application Priority Data
Jun. 30, 2016 (JP) 2016-129598

(51) Int. Cl. B62D 3/12; F16H 55/26; F16H 55/06; F16H 19/04; C23C 14/06

(52) U.S. Cl. CPC B62D 3/126; F16H 55/26; C23C 14/0605; F16H 19/04; F16H 55/06

(57) ABSTRACT

A vehicle rack-and-pinion mechanism (1), which is applicable to a steering device (S), includes: a pinion (11) that is formed with a gear tooth (12) and is supported so as to be rotatable about its axis; and a rack shaft (21) that is formed with a rack tooth (22) to engage with the gear tooth (12), wherein the rack tooth (22) is formed, on its surface, with a coating film (31) of coatings having different degrees of hardness laminated.

### TECHNICAL FIELD

The present invention relates to a vehicle rack-and-pinion mechanism used such as for a steering device of an automobile or the like.

### BACKGROUND OF THE INVENTION

A rack constituting a steering device of an automobile or the like has been subjected to heat treatment such as hardening to increase rigidity, toughness, and strength. For example, Patent Document 1 proposes induction hardening for a rack tooth formed on a steering rack shaft. If the whole steering rack shaft is hardened, the steering rack shaft may be distorted and bend in an arc shape. However, induction hardening only for the rack tooth allows for enhancing strength of the rack tooth while preventing the steering shaft from bending.

### PRIOR ART DOCUMENTS

### Patent Documents

Patent Document 1: Japanese Patent Application Publication No. H06-264147 A

### SUMMARY OF THE INVENTION

### Problems to be Solved

Incidentally, in the case of using a technique of increasing the strength of the rack tooth by heat treatment as in Patent Document 1, the upper limit value is determined depending on properties of a material forming the rack tooth. For this reason, when higher strength is required, the diameter of the rack itself needs to be larger to increase the contact area between the rack tooth and a pinion, but this causes a problem that a rack having a larger diameter is heavier.

Then, the present invention is intended to provide a vehicle rack-and-pinion mechanism that increases an allowable surface pressure of a rack tooth while avoiding the diameter of the rack itself from being increased and accordingly avoiding the weight of the rack from being increased.

### Solution to Problem

In order to achieve the above objective, a vehicle rack-and-pinion mechanism according to the present invention includes: a pinion that is provided with a gear tooth and is supported so as to be rotatable about its axis; and a rack shaft that is provided with a rack tooth to engage with the gear tooth, wherein the rack tooth is formed, on its surface, with a coating film of coatings having different degrees of hardness laminated.

### Advantageous Effects of the Invention

According to the present invention, a rack tooth of a rack-and-pinion mechanism composed of a material having a low specification value is formed with the coating film having the coatings laminated, to increase the tooth strength (allowable surface pressure) while avoiding the weight of the rack from being increased. This allows for providing a vehicle rack-and-pinion mechanism that increases the allowable surface pressure of the rack tooth, while avoiding the diameter of the rack itself from being increased and accordingly avoiding the weight of the rack from being increased.

### BRIEF DESCRIPTION OF DRAWINGS

FIG. 1 is a schematic view of a steering device according to the present embodiment;

FIG. 2 is a cross-sectional view of main parts of a rack tooth constituting a vehicle rack-and-pinion mechanism;

FIG. 3 is a cross-sectional view of a coating film formed on the rack tooth;

FIG. 4 is a time chart showing a temporal change in the composition of a stock gas supplied into equipment;

FIG. 5 is a schematic view of the hardness of the coating film

FIG. 6 illustrates differences in loads reaching a base material, depending on the composition of the coating film;

FIG. 7A is a schematic view of the load applied to the rack tooth being transmitted to the base material in a case where the coating film is composed of only one hard layer;

FIG. 7B is a schematic view of the load applied to the rack tooth being transmitted to the base material in a case where three laminar set layers are laminated;

FIG. 8 is a schematic view of tooth tops of the rack tooth and the gear tooth in a state that the steering device is assembled;

FIG. 9 is a schematic view of tooth tops of the rack tooth and the gear tooth through initial sliding;

FIG. 10 is a chart showing a relationship, conditioned by the coating film, between the number of sliding actions and abrasion of the gear tooth;

FIG. 11 is a cross-sectional view of the coating film formed on the rack tooth according to a first alternative aspect;

FIG. 12 is a time chart showing a temporal change in the composition of a stock gas supplied into the equipment, according to the first alternative aspect;

FIG. 13 is a cross-sectional view of the coating film formed on the rack tooth according to a second alternative aspect; and

FIG. 14 is a time chart showing a temporal change in the composition of a stock gas supplied into the equipment, according to the second alternative aspect.

### EMBODIMENTS OF THE INVENTION

An embodiment of the present invention will be described in detail with reference to the drawings as appropriate. Identical components are denoted by the same reference numerals, and duplicate descriptions thereof are omitted.

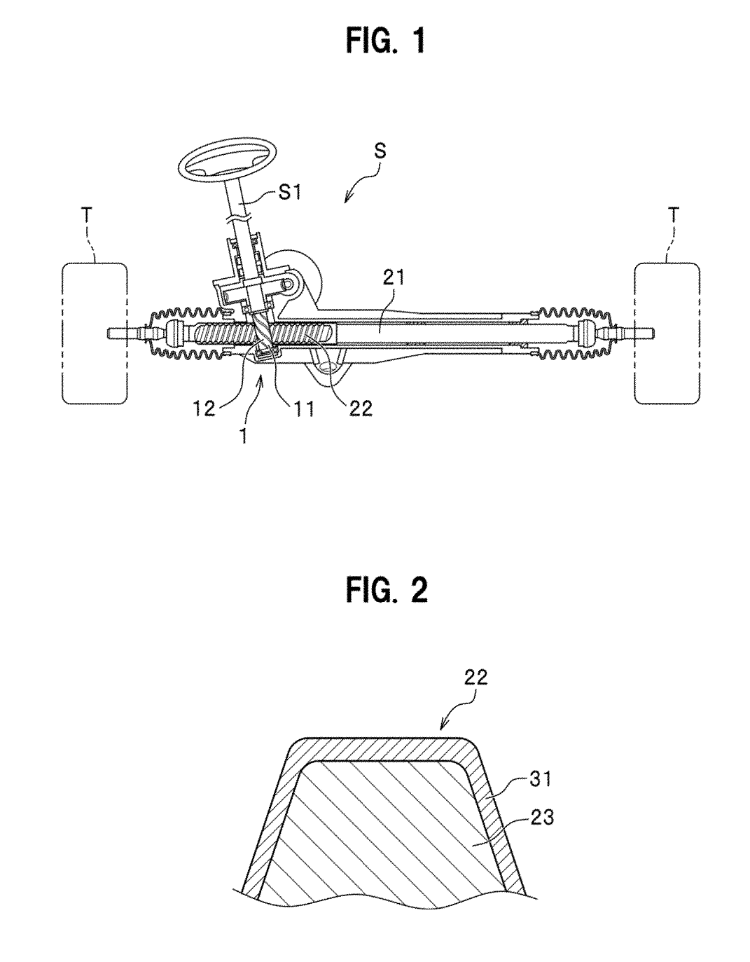

As shown in FIG. 1, a vehicle rack-and-pinion mechanism 1 of the present embodiment includes: a pinion 11 that is formed with a gear tooth 12 and rotatably supported about its axis; and a rack shaft 21 that is formed with a rack tooth 22 to be engaged with the gear tooth 12. In addition, the vehicle rack-and-pinion mechanism 1 of the present embodiment constitutes a steering device S of a vehicle. In other words, the pinion 11 constitutes a steering shaft S1 and is rotated about the axis in conjunction with the steering operation. Then, as the pinion 11 rotates, the engaging rack tooth 22 slides to change the steering angle of a tire T.

When the gear tooth 12 and the rack tooth 22 engage with each other in this steering device S, quietness is highly required and a large load is applied such as with steering without driving. Therefore, the gear tooth 12 and the rack tooth 22 are each composed of a helical tooth in the vehicle rack-and-pinion mechanism 1.

As the gear tooth 12 and the rack tooth 22 are each composed of a helical tooth, a portion of the gear tooth 12 engaged with the rack tooth 22 is translated in a tooth-width direction with the rotation of the pinion 11. As a result, the load is evenly applied to the gear tooth 12 while being translated in the tooth-width direction, to avoid local abrasion and reduce abrasion itself. In contrast, a portion of the rack tooth 22 having the load applied thereto is limited to a specific part, and the rack tooth 22 is locally abraded around this portion, to cause rattling during steering operation. Therefore, in the present embodiment, a coating film 31 is formed on the surface of the rack tooth 22, as shown in FIG. 2, to increase the strength and increase the allowable surface pressure so that uneven abrasion of the rack tooth 22 is avoided, to reduce excessive abrasion of both the rack tooth 22 and the gear tooth 12.

Note that the pinion 11 and the rack shaft 21 are made of an iron-based steel material (S35C, S45C, SCM 440, and the like) to have a Vickers hardness of about Hv 750 through hardening treatment such as hardening. The hardness of the coating film 31 formed on the surface of the rack tooth 22 is defined to be about three times the hardness of a base material 23 (i.e., about Hv 2250 with respect to the base material 23 having the hardness of about Hv 750), and is set to about Hv 2850 in further consideration of the hardness margin with respect to the degree of roughness of surfaces of abraded members.

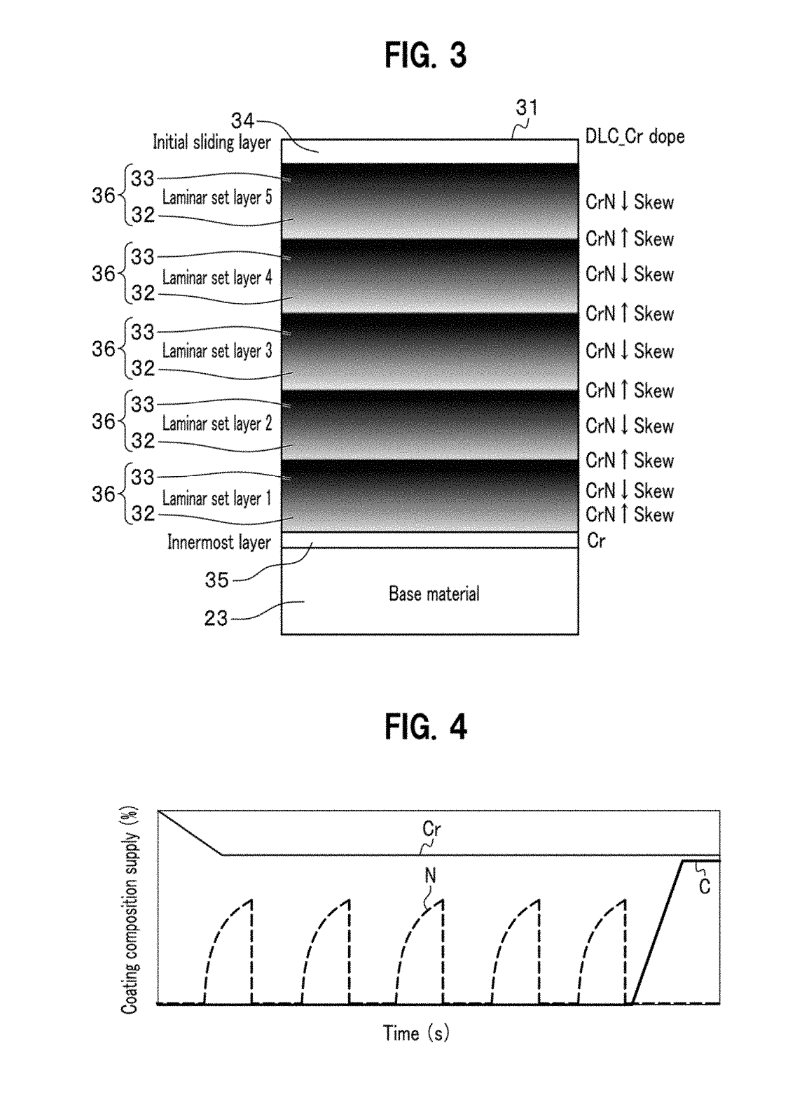

As shown in FIG. 3, the coating film 31 has multiple coatings laminated on the surface of the base material 23 of the rack tooth 22. These coatings are composed of four layers: an innermost layer 35, a soft layer 32, a hard layer 33, and an initial sliding layer 34. The innermost layer 35 is a layer in contact with the base material 23, and is composed of chromium (Cr). The innermost layer 35 has one or more laminar sets 36 laminated on its outer side, where each laminar set is composed of the soft layer 32 and the hard layer 33. The laminar set 36 is composed of chromium nitride (CrN, Cr2N) and its hardness changes depending on the percentage of nitrogen. As the soft layer 32 transitions to the hard layer 33, the percentage of nitrogen increases to have increased hardness. In the present embodiment, the five laminar sets 36 are laminated on the outer side of the innermost layer 35. Additionally, the initial sliding layer 34 is laminated on an outer surface of the outmost hard layer 33.

The initial sliding layer 34 is a layer to form the surface of the coating film 31 and is composed of chromium (Cr) and diamond-like carbon (DLC), and the percentage of DLC is set to be higher than that of chromium. This makes the hardness of the initial sliding layer closer to that of the hard layer, rather than to that of the soft layer. In other words, the innermost layer 35 has the highest percentage of chromium among the coatings constituting the coating film 31. Note that chromium and chromium nitride are selected to compose the innermost layer 35, the soft layer 32, and the hard layer 33 for the following reasons:
chromium has almost the same hardness as the base material 23 to have high adhesion to the base material 23;
chromium nitride has a hardness satisfying the required hardness (about 3 times as hard as a counterpart member); and
switching between chromium and chromium nitride at the time of lamination only requires changing the percentage of nitrogen contained in the stock gas to be supplied into the equipment, to provide an easy way of laminating coatings.

For forming the coating film 31, general PVD (Physical Vapor Deposition) equipment is used. The composition of the stock gas to be supplied into the PVD equipment is changed over time to change the composition of respective coatings in the coating film 31, so that the innermost layer 35, the soft layer 32, the hard layer 33, and the initial sliding layer 34 are laminated in one step. For example, as shown in FIG. 4, the step is started with supplying the stock gas into the equipment filled with an inert gas such as argon. At this point, the composition of the stock gas supplied is only chromium. When the innermost layer 35 made of chromium has been formed, nitrogen (N) is added to the stock gas at a predetermined rate. Then, chromium and nitrogen combine with each other to form chromium nitride, to have chromium nitride gradually increased in the composition of a coating. The coating formed in this way is the soft layer 32 composed of chromium and chromium nitride, and the percentage of nitrogen is further increased to form a coating of the hard layer 33. That is, one laminar set 36 is formed. When supplying nitrogen is stopped, the synthesis of chromium nitride stops and the composition of a coating to be formed has chromium increased relatively to form the soft layer 32 of the next laminar set 36. After forming the laminar set 36 is repeated five times, supplying nitrogen is stopped and supplying carbon (C) is started. In other words, the stock gas is now composed of chromium and carbon, and a coating to be formed is the initial sliding layer 34 composed of chromium and DLC. Through the above step, one innermost layer 35, five laminar sets 36, and one initial sliding layer 34 are formed on the surface of the base material 23.

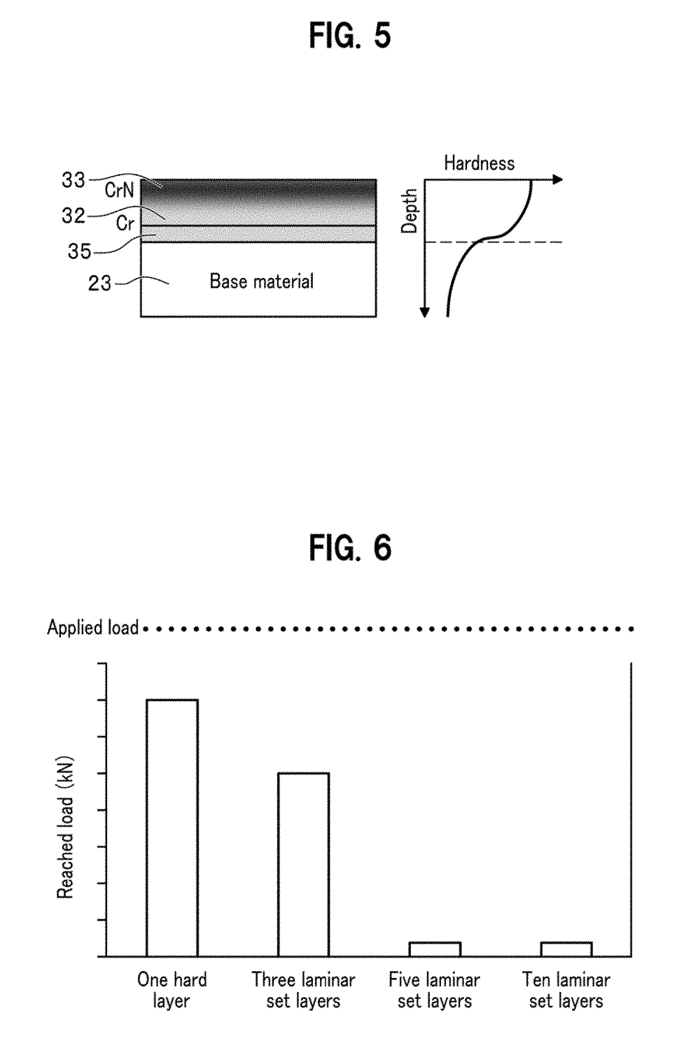

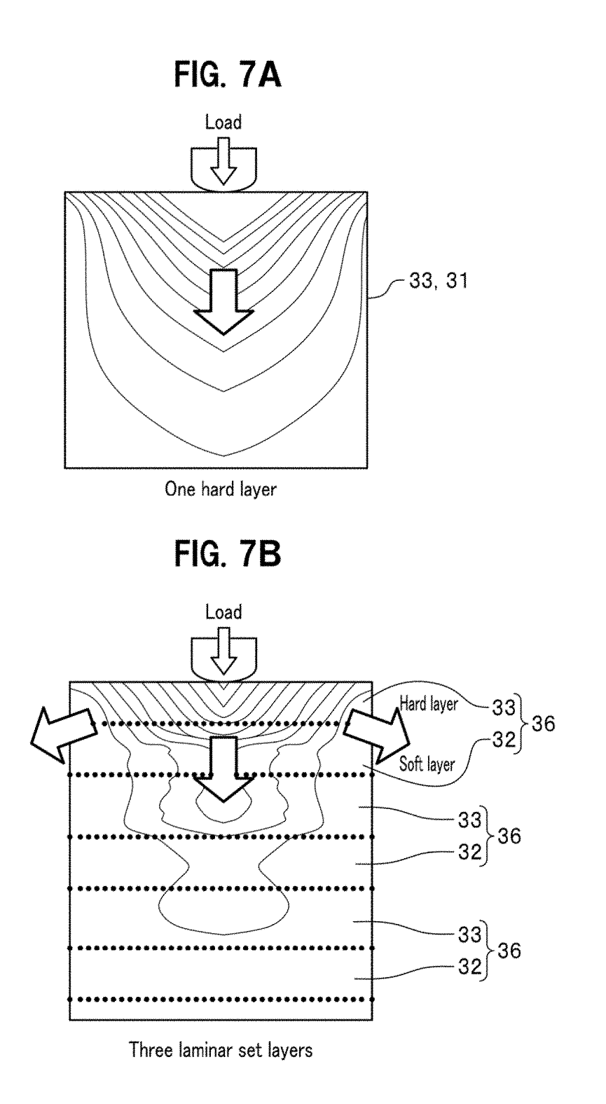

In addition, as the composition of the coatings gradually changes along the film-thickness direction, the hardness also changes gradually along the film-thickness direction, as shown in FIG. 5. This reduces separation between the coatings, even when an impact load is applied to the rack tooth 22. For example, if one layer of the hard layer 33 is formed as the coating film 31 on the surface of the base material 23, the input load almost reaches the surface of the base material 23 as it initially was, as shown in FIG. 6. However, if three or more laminar sets 36 are laminated as the coating film 31, the load reaching the surface of the base material 23 is found to be reduced. This is because the load applied from the gear tooth 12 to the rack tooth 22 is dispersed in the direction along the surface of the hard layer 33 due to the hard layer 33 being bent, as shown in FIGS. 7A and 7B. Alternately and repeatedly laminating the soft layer 32 and the hard layer 33 causes the applied load to be repeatedly dispersed in the respective hard layers 33. Therefore, as compared with the one hard layer 33, the repeatedly laminated hard layers 33 have an increased level of dispersion to allow for reducing the load reaching the surface of the base material 23. Laminating five or more laminar sets 36 allows for reducing the load reaching the surface of the base material 23 to a level less than 5% of the applied load (see FIG. 6). However, if the five or more laminar sets are laminated, increasing the number of laminar sets only gives small effects of dispersing the load, to have the same level of effect as that with the five laminar sets. Note that in the present embodiment, the coating film 31 is formed on the entire rack shaft 21 when the coating film 31 is formed on the rack tooth 22.

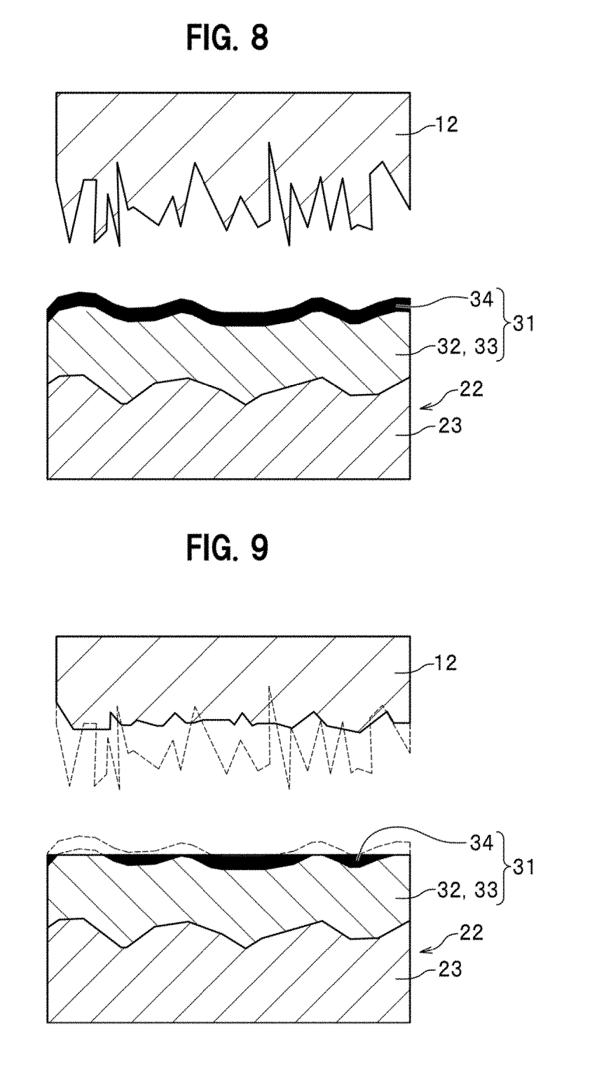

FIG. 8 shows tooth tops of the rack tooth 22 and the gear tooth 12 in a state that the rack shaft 21 having the rack tooth 22 coated with the coating film 31 and the pinion 11 are assembled as the steering device S. The rack tooth 22 has its surface smoothed to some extent by the coating film 31, but the gear tooth 12 has its surface left rough as it was after the cutting process. Note that the soft layer 32 and the hard layer 33 are drawn as if they were in one layer in FIG. 8, for the purpose of illustration, but the soft layers 32 and the hard layers 33 are alternately laminated, as described above.

In addition, FIG. 9 shows the tooth tops of the rack tooth 22 and the gear tooth 12 through initial sliding by repeatedly turning the steering device S about 20,000 times. Note that the soft layer 32 and the hard layer 33 are drawn as if they were in one layer also in FIG. 9, for the purpose of illustration, but the soft layers 32 and the hard layers 33 are alternately laminated, as described above. The surface of the gear tooth 12 of the pinion 11 and the initial sliding layer 34 of the rack tooth 22 abrade each other and are smoothed through the initial sliding. That is, the initial sliding layer 34 of the rack tooth 22 scrapes off and smoothes rough portions of the surface of the gear tooth 12, and the initial sliding layer 34 itself is also abraded. Further, as the hardness of DLC composing the initial sliding layer 34 is set to fall between the hardness of the soft layer 32 and the hardness of the hard layer 33, rough portions of the surface of the gear tooth 12 are gradually scraped off, to make particles of abrasive powder finer. As the particles are made finer, the abrasion powder enters a small gap on the surface of the gear tooth 12, to further improve the smoothness. Furthermore, forming the initial sliding layer 34 with DLC reduces a phenomenon that abrasive powder generated by scraping reattaches to the gear tooth 12 and the rack tooth 22 to scrape off the counterpart member. This reduces excessive abrasion of the sliding portions.

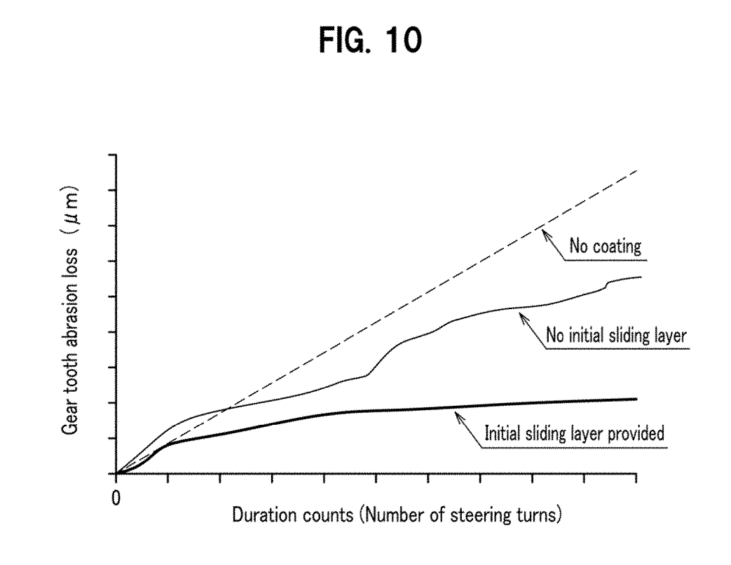

The rack tooth 22 and the gear tooth 12 have stabilized sliding after the tooth tops thereof have been smoothed by the initial sliding, and are prevented from both being abraded (see FIG. 10). It is found that abrasion of the pinion 11 is sufficiently reduced even with the coating film 31 in which the soft layers 32 and the hard layers 33 are alternately laminated, as compared with a conventional product in which no coating film 31 is formed, but the abrasion is further reduced with the coating film 31 having the initial sliding layer 34 laminated on the outermost surface thereof. The vehicle rack-and-pinion mechanism 1 in the steering system S of the vehicle is required to be maintenance-free so that no maintenance and inspection are required, and reducing abrasion as described above achieves this. Additionally, the coating film 31 having the above-described composition and hardness is formed on the rack tooth 22 in the present embodiment, and this allows the rack shaft 21 to be reduced in size and to be hollowed so that the weight of the entire steering device S is reduced.

Next, a description will be given of advantageous effects of the vehicle rack-and-pinion mechanism 1 according to the present embodiment. Forming the coating film 31, which has multiple coatings laminated, on the rack tooth 22 of the vehicle rack-and-pinion mechanism 1, which is composed of an inexpensive material having low specification values, allows the rack tooth 22 to have increased strength (allowable surface pressure), while using an expensive material is avoided to prevent manufacturing costs from increasing.

Alternately and repeatedly laminating the soft layers 32 and the hard layers 33 allows for dispersing the load applied from the gear tooth 12 to the rack tooth 22 in the direction along the surfaces of the respective hard layers 33. This allows the stress on the substrate 23 to be relaxed to prevent the coating film 31 from being separated.

As chromium has high adhesion to an iron-based steel material and chromium nitride, using chromium and chromium nitride to form the soft layer 32 and the hard layer 33 allows the rack tooth 22 to have, on its surface, the coating film 31 which is rigid and hardly separated. This further increases the strength (allowable surface pressure) of the rack tooth 22. In addition, in the step of alternately and repeatedly laminating the soft layers 32 and the hard layers 33, changing the percentages of chromium and nitrogen to be supplied into the laminating equipment allows for easily switching between forming the soft layers 32 and forming the hard layer 33, to simplify the procedure. Further, a good adsorption layer is provided for grease (having Mo added).

Laminating the three or more laminar sets 36 composed of the soft layers 32 and the hard layers 33 allows for more effectively achieving the function of dispersing the load applied from the gear tooth 12 of the pinion 11 to the rack tooth 22 in the direction along the surfaces of the respective hard layers 33.

Additionally, forming the initial sliding layer 34 on the outer surface of the outermost hard layer 33 allows for reducing abrasion of the rack tooth 22 itself and for smoothing the surface of the gear tooth 12 of the pinion 11 to reduce abrasion after the smoothing.

Setting the hardness of the initial sliding layer 34 closer to the hard layer 33 than to the soft layer 32 allows for further reducing abrasion of the rack tooth 22 itself.

Forming the initial sliding layer 34 with a DLC film prevents abrasion powder from reattaching to the rack tooth 22, to further reduce abrasion after the surface of the gear tooth 12 has been smoothed.

Arranging the innermost layer 35 including a high percentage of chromium, which has high adhesive to an iron-based steel material, on the surface of the base material 23 allows for increasing a level of adhesion of the coating film 31 to the base material 23. This allows for further reducing separation due to the applied load.

Changing the composition of films gradually along the film-thickness direction at boundaries between the respective layers composing the coating film 31 reduces separation at the boundaries of the respective layers, to form the more rigid, tougher coating film 31. On another note, as a general characteristic of the vehicle to which the steering device S is attached, the vicinities of both ends in the axial direction of the rack tooth 22 tend to have larger load applied than the vicinity of the center of the rack tooth 22. Therefore, the number of laminar sets 36 of the coating film 31 may be larger in the vicinities of the both ends of the rack tooth 22 than in the vicinity of the center of the rack tooth 22. Additionally, the number of the laminar sets 36 is adjustable by masking the vicinity of the center of the rack tooth 22 or the like.

Forming the coating film 31 on the entire rack shaft 21 in addition to the rack tooth 22 allows for executing rust prevention treatment to the entire rack shaft 21 in the step of forming the coating film 31 on the rack tooth 22.

Note that the initial sliding layer 34 of the present embodiment is composed of DLC, but the present invention is not limited to this. For example, molybdenum disulfide may be used for the initial sliding layer. In the case where the initial sliding layer is formed of a film of molybdenum disulfide, self-lubricating properties of molybdenum disulfide further reduces abrasion after initial sliding.

In addition, the coating film 31 is formed on the entire rack shaft 21 in the present embodiment, but the present invention is not limited to this. For example, the coating film 31 may be formed only on the rack tooth 22 to have no coating film 31 formed on the backside of the rack tooth 22 (portions other than the rack tooth 22) of the rack shaft 21. This allows for reducing costs of forming the coating film 31 and for preventing friction with a rack guide and abrasion caused by forming the coating film from increasing.

Next, a first alternative aspect of the present embodiment will be described. In the above-described embodiment, the percentage of nitrogen gradually increases along the film-thickness direction at a boundary changing from the soft layer 32 to the hard layer 33 (an in-laminar-set boundary 37), as shown in FIG. 3, to have an unclear boundary. Additionally, the percentage of nitrogen sharply changes at a boundary changing from the hard layer 33 to the soft layer 32, that is, a boundary between the adjacent laminar sets 36 (an inter-laminar-set boundary 38), to have a clear boundary.

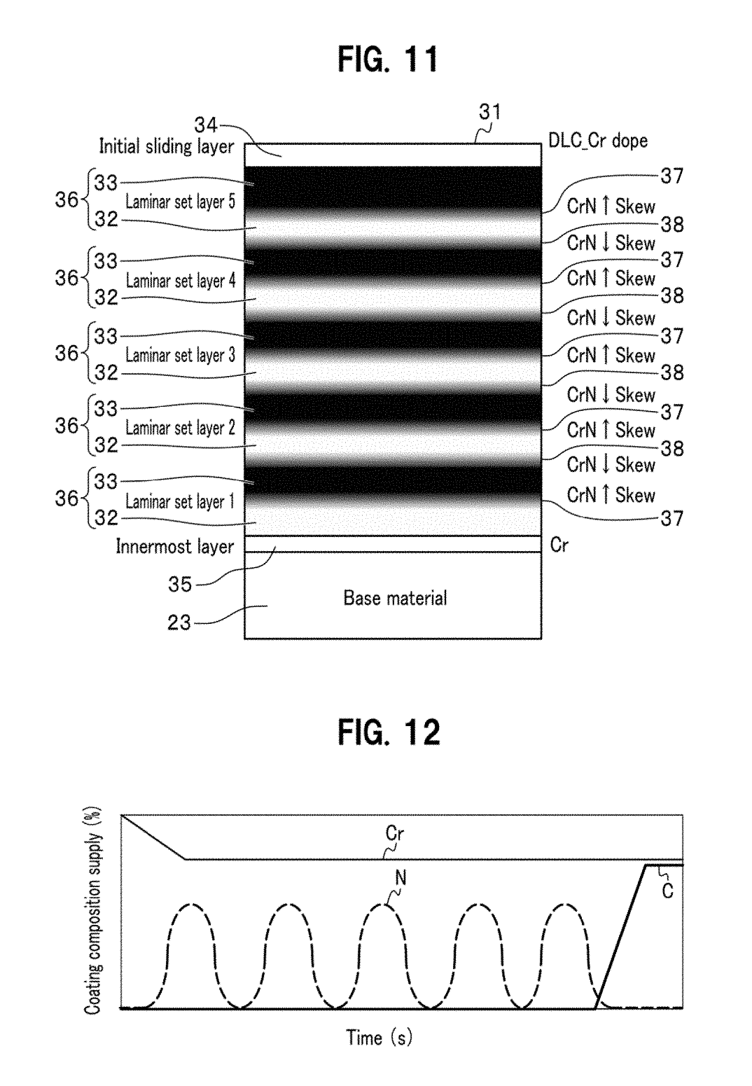

In contrast, in the present aspect, the percentage of chromium nitride gradually changes not only at the in-laminar-set boundary 37 but also at the inter-laminar-set boundary 38 along the film-thickness direction, as shown in FIG. 11. In other words, in the present aspect, the percentage of nitrogen gradually changes at the boundary between adjacent laminar sets 36 along the film-thickness direction, to have an unclear boundary between the adjacent laminar sets 36. Note that the innermost layer 35 and the initial sliding layer 34 have the same composition as in the above embodiment.

In order to form the coating film 31 in which the soft layer 32 and the hard layer 33 are gradually switched as in the present aspect, chromium, nitrogen, and carbon are supplied into the equipment in accordance with the time chart shown in FIG. 12. In the time chart of the above-described embodiment, the supply pattern of nitrogen is set to have a rectangular wave shape, as shown in FIG. 4, whilst the supply pattern of nitrogen is set to have a sinusoidal shape in the present aspect, as shown in FIG. 12. Note that the supply pattern of chromium and carbon is set to be the same as in the above-described embodiment.

Adopting such a supply pattern allows for switching between the soft layer 32 and the hard layer 33 more smoothly. Note that the supply pattern for forming the coating film 31 is not limited to the pattern as indicated in the time chart in FIG. 12. Depending on how the hard layer 33 and the soft layer 32 are switched, the supply pattern will be changed to a more appropriate one, together with the temperature, pressure, and flow speed of the stock gas in the PVD equipment, and the like.

Next, advantageous effects of the present aspect will be described. In the present aspect, the percentage of chromium nitride gradually increases and decreases at the in-laminar-set boundary 37 and the inter-laminar-set boundary 38 along the film-thickness direction, as shown in FIG. 11. With such a configuration, the degree of change in the hardness in the film-thickness direction is reduced at the boundaries between the soft layers 32 and the hard layers 33, to further reduce separation due to the applied load at the boundaries between the respective layers. This allows for forming the more rigid, tougher coating film 31.

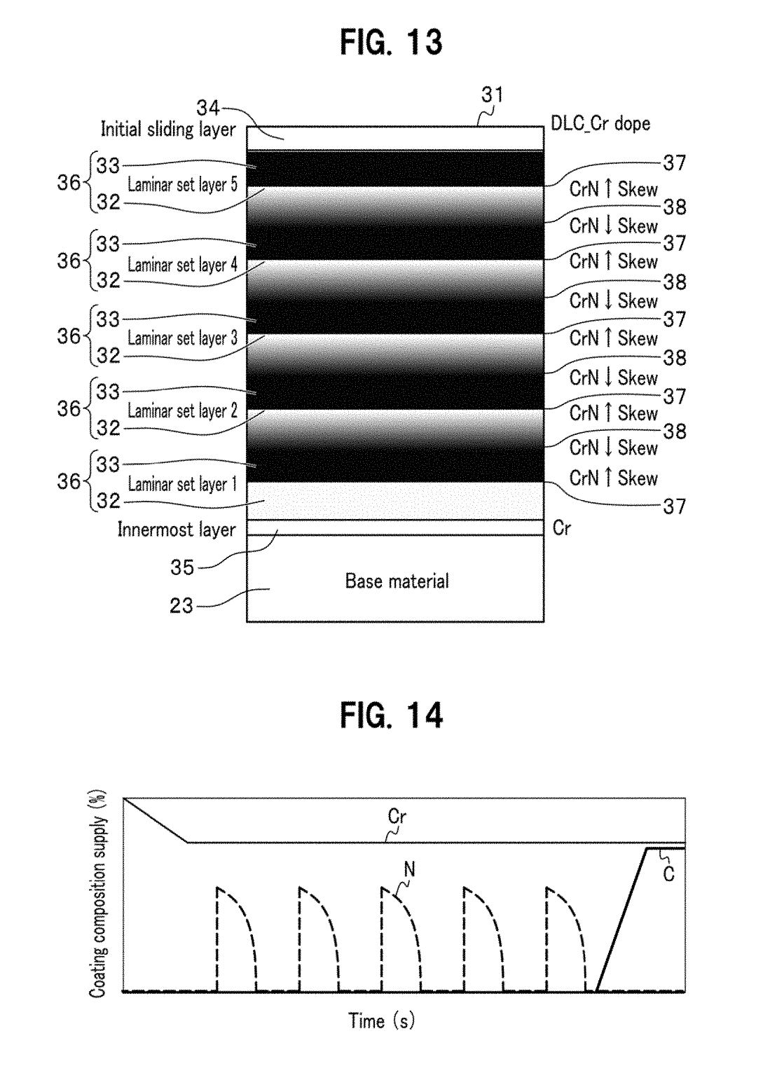

Next, a second alternative aspect of the present embodiment will be described. In the present aspect, the percentage of chromium nitride sharply changes at the in-laminar-set boundary 37, as shown in FIG. 13. Additionally, the percentage of chromium nitride gradually decreases at the inter-laminar-set boundary 38 along the film-thickness direction. In other words, unlike the above-described embodiment, a clear boundary is formed in each laminar set 36, and the boundary between adjacent laminar sets 36 is unclear. In order to form the coating film 31 as in the present aspect, chromium, nitrogen, and carbon are supplied into the equipment in accordance with the time chart shown in FIG. 14. Note that the innermost layer 35 and the initial sliding layer 34 have the same composition as in the above-described embodiment.

Next, advantageous effects of the present aspect will be described. As shown in FIG. 13, the percentage of chromium nitride gradually increases at the inter-laminar-set boundary 38 of the present aspect along the film-thickness direction. This allows for forming the rigid, tough coating film 31 as in the above-described embodiment. In addition, the number of boundaries where the percentage of chromium nitride gradually changes is smaller than that in the first alternative aspect, to allow for forming the coating film 31 in a shorter time and making the thickness of the coating film 31 thinner.

Note that in the above-described embodiment, the first alternative aspect, and the second alternative aspect, the soft layer 32 and the hard layer 33 are composed of chromium and nitrogen, but the present invention is not limited thereto. For example, the soft layer 32 and the hard layer 33 may be formed of a combination of tungsten and nitrogen, or titanium and nitrogen. In the case of a combination of tungsten and nitrogen, the soft layer 32 and the hard layer 33 are composed of tungsten and tungsten nitride, and their hardness changes according to the percentage of tungsten nitride. The hard layer 33 has a higher percentage of tungsten nitride than the soft layer 32, to have the higher hardness.

Similarly, in the case of a combination of titanium and nitrogen, the soft layer 32 and the hard layer 33 are composed of titanium and titanium nitride, and their hardness changes according to the percentage of titanium nitride. As in the case of tungsten, the hard layer 33 has a higher percentage of titanium nitride than the soft layer 32 to have the higher hardness. As described above, the ingredients of the soft layer 32 and the hard layer 33 are selectable from multiple candidates, and more suitable ingredients are adopted according to the required strength, forming speed, forming cost of the coating film 31, and the like. In addition, even when the soft layer 32 and the hard layer 33 formed of the selected ingredients are used, the same advantageous effects as those of the above-described embodiment are gained.

### LEGEND FOR REFERENCE NUMERALS

1 Rack-and-pinion mechanism
11 Pinion
12 Gear tooth
21 Rack shaft
22 Rack tooth
23 Base material
31 Coating film
32 Soft layer
33 Hard layer
34 Initial sliding layer
35 Innermost layer
36 Laminar set
38 Inter-laminar-set boundary

1. A vehicle rack-and-pinion mechanism comprising:
a pinion that is formed with a gear tooth and is supported so as to be rotatable about its axis; and
a rack shaft that is formed with a rack tooth to engage with the gear tooth,
wherein the rack tooth is formed, on its surface, with a coating film of coatings having different degrees of hardness laminated.

2. The vehicle rack-and-pinion mechanism according to claim 1,
wherein the coating film includes two coatings of a soft layer and a hard layer, which is set to be harder than the soft layer, and the soft layer and the hard layer are alternately and repeatedly laminated in this order on a surface of a base material of the rack tooth, to have the hard layer on the outermost surface.

3. The vehicle rack-and-pinion mechanism according to claim 2,
wherein the soft layer and the hard layer are formed of a combination of chromium and nitrogen, tungsten and nitrogen, or titanium and nitrogen,
wherein the soft layer is set to have a higher percentage of chromium, tungsten, or titanium than that of nitrogen, and
the hard layer is set to have a higher percentage of nitrogen than that of chromium, tungsten, or titanium.

4. The vehicle rack-and-pinion mechanism according to claim 3,
wherein the coating film is laminated with three or more laminar sets, each composed of the soft layer and the hard layer.

5. The vehicle rack-and-pinion mechanism according to claim 3,
wherein the coating film is laminated with five or more laminar sets, each composed of the soft layer and the hard layer.

6. The vehicle rack-and-pinion mechanism according to claim 4,
wherein the laminar set has a percentage of nitrogen gradually changed from the soft layer to the hard layer along a film-depth direction.

7. The vehicle rack-and-pinion mechanism according to claim 4,
wherein a boundary between the adjacent laminar sets has a percentage of nitrogen gradually changed along a film-depth direction.

8. The vehicle rack-and-pinion mechanism according to claim 4,
wherein the number of layers of the laminar sets in the coating film is set depending on a relative position in a tooth-width direction and a relative position in an axial direction of the rack shaft, on the rack tooth.

9. The vehicle rack-and-pinion mechanism according to claim 2,
wherein the coating film includes an initial sliding layer on an outer surface of the outermost hard layer.

10. The vehicle rack-and-pinion mechanism according to claim 9,
wherein the hardness of the initial sliding layer is set closer to the hard layer than to the soft layer.

11. The vehicle rack-and-pinion mechanism according to claim 9,
wherein the initial sliding layer is composed of a coating of diamond-like carbon or molybdenum disulfide.

12. The vehicle rack-and-pinion mechanism according to claim 3,
wherein an innermost layer, having the highest percentage of chromium, tungsten, or titanium among the coatings composing the coating film, is provided between the soft layer closest to the surface of the base material of the rack tooth and the surface of the base material.

13. The vehicle rack-and-pinion mechanism according to claim 1,
wherein the coating film is formed on the entire rack shaft.
